(19) United States
(12) Patent Application Publication
(10) Pub. No.: US 2025/0311112 A1
(43) Pub. Date: Oct. 2, 2025

(54) MANUFACTURING METHOD OF WIRING SUBSTRATE

(71) Applicant: SHINKO ELECTRIC INDUSTRIES CO., LTD., Nagano-shi (JP)

(72) Inventor: Tomoaki Machida, Nagano (JP)

(21) Appl. No.: 19/085,617

(22) Filed: Mar. 20, 2025

(30) Foreign Application Priority Data
Mar. 29, 2024 (JP) 2024-057343

(51) Int. Cl. H05K 3/40; H05K 1/11; H05K 1/18; H05K 3/00; H05K 3/28; H05K 3/30; H05K 3/34

(52) U.S. Cl. CPC H05K 3/4007; H05K 1/116; H05K 1/186; H05K 3/0026; H05K 3/282; H05K 3/301; H05K 3/34; H05K 3/4038; H05K 2201/09481; H05K 2201/096; H05K 2201/09618

(57) ABSTRACT

A manufacturing method of a wiring substrate includes laminating a seed layer on a top surface of a first insulating layer; forming, on a top surface of the seed layer, a pad that includes a pad main body, and a surface treatment layer that covers a top surface and a side surface of the pad main body, and that has a metal layer at least in part; forming a protective film that covers a surface of the pad and the top surface of the seed layer around the pad; forming a second insulating layer that covers a surface of the protective film on the top surface of the first insulating layer; forming a cavity that exposes the surface of the protective film in the second insulating layer by laser processing; removing the protective film; and removing a portion of the seed layer that does not overlap with the pad.

### CROSS-REFERENCE TO RELATED APPLICATION

This application is based upon and claims the benefit of priority of the prior Japanese Patent Application No. 2024-057343, filed on Mar. 29, 2024, the entire contents of which are incorporated herein by reference.

### FIELD

The embodiments discussed herein are related to manufacturing method of a wiring substrate.

### BACKGROUND

In recent years, wiring substrates that incorporate an electronic component, such as a capacitor, within a substrate have gained recognition to achieve high-density component mounting. A wiring substrate that embeds an electronic component is manufactured, for example, by arranging a cavity in an insulating layer of a substrate in which layers constituted of an insulating layer and a wiring layer are laminated, and by injecting filling resin to fill the cavity in which an electronic component is arranged.

The electronic component is joined to a pad of the wiring layer exposed in the cavity using solder. Specifically, a seed layer made of a metal such as copper is formed on a surface of the insulating layer that constitutes the wiring substrate, and on a top surface of this seed layer, a wiring layer that includes pads made of a metal such as copper is formed. Subsequently, an unnecessary portion of the seed layer is removed such that the seed layer around the pad in a region in which the cavity is to be formed remains. Subsequently, another insulating layer is formed on the surface of the insulating layer, covering the surface of the pad and the top surface of the seed layer around the pad. By laser processing, a cavity is formed in the other insulating layer to expose the surface of the pad and the top surface of the seed layer around the pad. Thereafter, in the cavity, an unnecessary portion that does not overlap with the pad is removed, and the pad and an electrode of the electronic component are joined via solder (JP-T-2023-533233).

However, in the process of forming the cavity using laser processing, a laser is directly irradiated onto the pad and the seed layer around the pad that are exposed in the cavity. As a result, there is a problem in which the pad and the seed layer around the pad deteriorate due to the heat from the irradiated laser.

### SUMMARY

According to an aspect of an embodiment, a manufacturing method of a wiring substrate includes laminating a seed layer that is made of a metal on a top surface of a first insulating layer; forming, on a top surface of the seed layer, a pad that includes a pad main body made of a metal, and a surface treatment layer that covers a top surface and a side surface of the pad main body, and that has a metal layer made of a metal different from that of the pad main body at least in part; forming a protective film that covers a surface of the pad and the top surface of the seed layer around the pad; forming a second insulating layer that covers a surface of the protective film on the top surface of the first insulating layer; forming a cavity that exposes the surface of the protective film in the second insulating layer by laser processing; removing the protective film that is exposed in the cavity, by etching; and removing a portion of the seed layer that does not overlap with the pad.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a wiring substrate according to a first embodiment;

FIG. 2 is an enlarged view illustrating an area around a pad;

FIG. 3 is a flowchart illustrating a manufacturing method of the wiring substrate according to the first embodiment;

FIG. 4 is a diagram illustrating a specific example of a build-up process;

FIG. 5 is a diagram illustrating a specific example of a via-hole formation process;

FIG. 6 is a diagram illustrating a specific example of a seed-layer formation process;

FIG. 7 is a diagram illustrating a specific example of a resist-layer formation process;

FIG. 8 is a diagram illustrating a specific example of an electrolytic plating process;

FIG. 9 is a diagram illustrating a specific example of a resist-layer removal process;

FIG. 10 is a diagram illustrating a specific example of a resist-layer formation process;

FIG. 11 is a diagram illustrating a specific example of a surface-treatment-layer formation Process;

FIG. 12 is a diagram illustrating a specific example of a resist-layer removal process;

FIG. 13 is a diagram illustrating a specific example of a resist-layer formation process;

FIG. 14 is a diagram illustrating a specific example of a protective-film formation process;

FIG. 15 is a diagram illustrating a specific example of a resist-layer removal process;

FIG. 16 is a diagram illustrating a specific example of an insulating-layer formation process;

FIG. 17 is a diagram illustrating a specific example of a cavity formation process;

FIG. 18 is a diagram illustrating a specific example of a protective-film removal process;

FIG. 19 is a diagram illustrating a specific example of an electronic-component mounting process;

FIG. 20 is a diagram illustrating a specific example of an electronic-component embedding process;

FIG. 21 is a diagram illustrating a specific example of a via-hole formation process;

FIG. 22 is a diagram illustrating a specific example of a wiring formation process;

FIG. 23 is a diagram illustrating a specific example of a solder-resist-layer formation process;

FIG. 24 is a diagram explaining variations in thickness of the protective film;

FIG. 25 is a diagram explaining how galvanic corrosion occurs on a surface treatment layer;

FIG. 26 is a flowchart illustrating a manufacturing method of a wiring substrate according to a second embodiment;

FIG. 27 is a diagram illustrating a specific example of a protective-film formation process;

FIG. 28 is a diagram illustrating a specific example of a resist-layer removal process;

FIG. 29 is a diagram illustrating a specific example of an insulating-layer formation process;

FIG. 30 is a diagram illustrating a specific example of a cavity formation process;

FIG. 31 is a diagram illustrating a first modification of the protective-film formation process; and

FIG. 32 is a diagram illustrating a second modification of the protective-film formation process.

### DESCRIPTION OF EMBODIMENTS

Hereinafter, embodiments of a manufacturing method of a wiring substrate disclosed in the present application will be explained in detail with reference to the drawings. The embodiments are not intended to limit the disclosed technique.

### First Embodiment

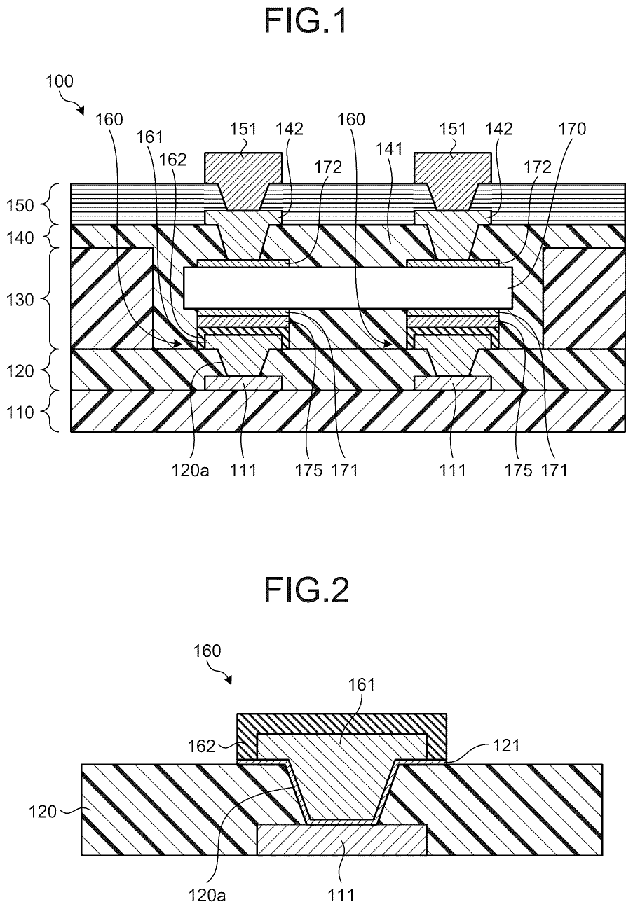

FIG. 1 is a diagram illustrating a configuration of a wiring substrate 100 according to a first embodiment. FIG. 1 schematically illustrates a cross-section of the wiring substrate 100. In the following, it will be explained supposing that a solder resist layer 150 is the upper most layer as illustrated in FIG. 1, but the wiring substrate 100 may be manufactured and used, for example, with upside down orientation, and may be manufactured and used in any orientation.

The wiring substrate 100 has a laminated structure, and includes an insulating layers 110, 120, 130, a wiring layer 111, a filling resin layer 140, and the solder resist layer 150. In the insulating layer 130, an electronic component 170 is embedded. Although illustration is omitted in FIG. 1, another insulating layer and a wiring layer may be formed below the insulating layer 110 and, for example, a core layer made of a material, such as glass, may be formed.

The insulating layer 110 is formed using an insulating resin mainly composed of, for example, epoxy resin or polyimide resin. As the insulating resin, for example, thermosetting insulating resin or photosensitive insulating resin may be used.

The wiring layer 111 is patterned into a predetermined planar shape on a top surface of the insulating layer 110. As a material of the wiring layer 111, for example, copper (Cu) and the like can be used. The wiring layer 111 may be connected to a wiring layer not illustrated below the insulating layer 110 via a via wiring, not illustrated, that penetrates through the insulating layer 110, or the like.

The insulating layer 120 is formed to cover the wiring layer 111 on the top surface of the insulating layer 110. A material of the insulating layer 120 may be, for example, same as that of the insulating layer 110. The insulating layer 120 is one example of a first insulating layer.

In the insulating layer 120, a via hole 120a that penetrates through the insulating layer 120 and that exposes a top surface of the wiring layer 111 from its bottom portion is formed. The via hole 120a may be a through hole in an inverted truncated conical shape in which a diameter of an opening portion that opens toward a top surface of the insulating layer 120 is larger than a diameter of an opening portion at a bottom portion exposing the top surface of the wiring layer 111. At a position corresponding to the via hole 120a, a pad 160 that is an electrode protruding from the top surface of the insulating layer 120, and that is electrically connected to a lower electrode pad 171 of the electronic component 170 is formed. The configuration of the pad 160 will be described later.

Although illustration is omitted in FIG. 1, on the top surface of the insulating layer 120, another wiring layer including the pad 160 is formed, and this wiring layer is connected to the wiring layer 111 on the top surface of the insulating layer 110 through the via that penetrates through the insulating layer 120.

The insulating layer 130 is formed on the top surface of the insulating layer 120 to cover the other wiring layer including the pad 160. A material of the insulating layer 130 may be, for example, same as that of the insulating layers 110 and 120. The insulating layer 130 is one example of a second insulating layer.

In the insulating layer 130, the electronic component 170 is embedded. In the insulating layer 130, a cavity to house the electronic component 170 is formed. Inside the cavity, the pad 160 is positioned.

Although illustration is omitted in FIG. 1, on the top surface of the insulating layer 130, another wiring layer is formed, and this wiring layer is connected to the other wiring layer on the top surface of the insulating layer 120 through a via that penetrates through the insulating layer 130.

The filling resin layer 140 is a layer that is formed continuously with a filling resin 141 filled in the cavity in an electronic-component embedding processing described later. On a top surface of the filling resin layer 140, wirings 142 is formed, and these wirings 142 are covered with the solder resist layer 150. In the filling resin layer 140, a via is formed as necessary after the electronic-component embedding process, and the wirings 142 on the top surface of the filling resin layer 140 is connected to an upper electrode pad 172 of the electronic component 170 or is connected to the other wiring layer on the top surface of the insulating layer 130. The resin to form the filling resin layer 140 may be, for example, an insulating resin similar to those of the insulating layers 110 and 120.

The solder resist layer 150 is a layer that covers wirings (in this example, the wirings 142 on the top surface of the filling resin layer 140) arranged on an outermost surface of the wiring substrate 100, to protect the wirings. The solder resist layer 150 is film-formed by, for example, pattern printing. For example, at a portion at which an external component, such as a semiconductor chip, is mounted, an opening is arranged in the solder resist layer 150, and a bump 151 connected to the wiring 142 on the top surface of the filling resin layer 140 is formed.

The electronic component 170 is an electronic component, such as a capacitor, and is embedded in the insulating layer 130. That is, in the cavity formed in the insulating layer 130, the lower electrode pad 171 of the electronic component 170 and the pad 160 are joined by solder 175, and the filling resin 141 is filled around the electronic component 170 and the pad 160. Thus, the electronic component 170 is embedded in the wiring substrate 100.

Next, referring to FIG. 2, a configuration of the pad 160 will be specifically explained. FIG. 2 is an enlarged view of an area around the pad 160. The pad 160 is a protruding electrode that is formed protruding from the top surface of the insulating layer 120, and has a pad main body 161 and a surface treatment layer 162.

The pad main body 161 is an electrode to be a main body of the pad 160, and is formed by electrolytic plating with, for example, copper (Cu). Specifically, a seed layer 121 is formed on the top surface of the insulating layer 120, and the pad main body 161 is formed on a top surface of the seed layer 121 by electrolytic plating. The seed layer 121 is formed on the top surface of the insulating layer 120 by sputtering or non-electrolytic plating using, for example, copper (Cu) as a material.

The surface treatment layer 162 is a metal layer that covers a top surface and a side surface of the pad main body 161, and that comes in contact with the top surface of the seed layer 121, and is formed by electrolytic plating or non-electrolytic plating, for example, with gold (Au). As the surface treatment layer 162, instead of a gold (Au) layer, a multilayer film constituted of a nickel (Ni) layer, a palladium (Pd) layer, and a gold (Au) layer, or a multilayer fil constituted of a palladium (Pd) layer and a gold (Au) layer may be used. That is, the surface treatment layer 162 has a layer of gold (Au) that is a different metal from the seed layer 121 and the pad main body 161 at least in part. In the case in which the surface treatment layer 162 is the multilayer film constituted of a nickel (Ni) layer, a palladium (Pd) layer, and a gold (Au) layer, it is preferable that the nickel (Ni) layer, the palladium (Pd) layer, and the gold (Au) layer be formed sequentially in this order from a side closer to the pad main body 161 by electrolytic plating or non-electrolytic plating. Moreover, in the case in which the surface treatment layer 162 is the multilayer film constituted of a palladium (Pd) layer and a gold (Au) layer, it is preferable that the palladium (Pd) layer and the gold (Au) layer be formed sequentially in this order from a side closer to the pad main body 161 by electrolytic plating or non-electrolytic plating.

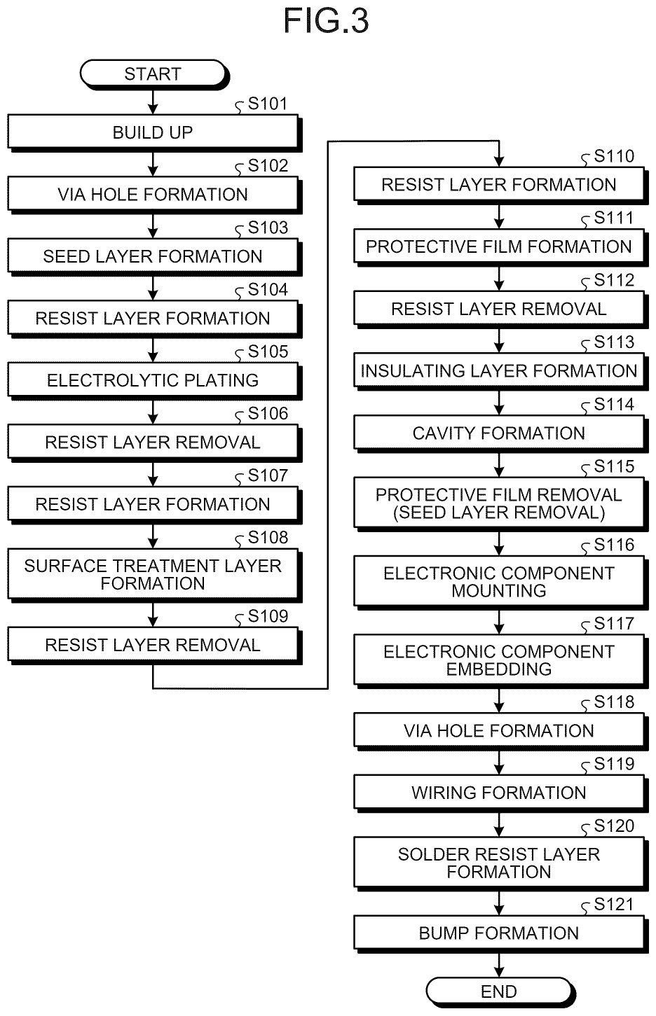

Next, a manufacturing method of the wiring substrate 100 configured as described above will be explained referring to FIG. 3. FIG. 3 is a flowchart illustrating the manufacturing method of the wiring substrate 100 according to the first embodiment.

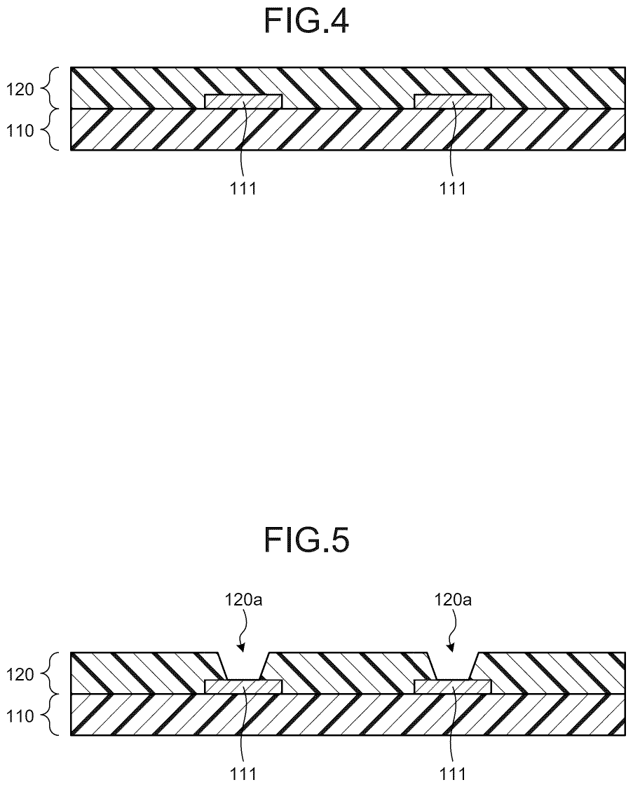

First, by a build-up method, the insulating layer 110, the wiring layer 111, and the insulating layer 120 are laminated (step S101). Specifically, for example, as illustrated in FIG. 4, the insulating layer 110 is formed on a top surface of another wiring layer, an insulating layer, a core layer, or the like not illustrated, and on the top surface of the insulating layer 110, the wiring layer 111 is formed. The wiring layer 111 is formed, for example, by a semi-additive method, by patterning, for example, copper (Cu) in a predetermined planar shape. On the top surface of the insulating layer 110, the insulating layer 120 is laminated to cover the wiring layer 111. FIG. 4 is a diagram illustrating a specific example of a build-up process.

Once the insulating layer 110, the wiring layer 111, and the insulating layer 120 are laminated, the via hole 120a is formed in the insulating layer 120 (step S102). That is, for example, as illustrated in FIG. 5, the via hole 120a that penetrates through the insulating layer 120, and that exposes the top surface of the wiring layer 111 from its bottom portion is formed. FIG. 5 is a diagram illustrating a specific example of a via-hole formation process. The via hole 120a can be formed by a laser processing method using, for example, CO₂, or the like. When the via hole 120a is formed by a laser processing method, desmear processing is performed to remove resin residues adhered to the top surface of the wiring layer 111 exposed from the bottom portion of the via hole 120a.

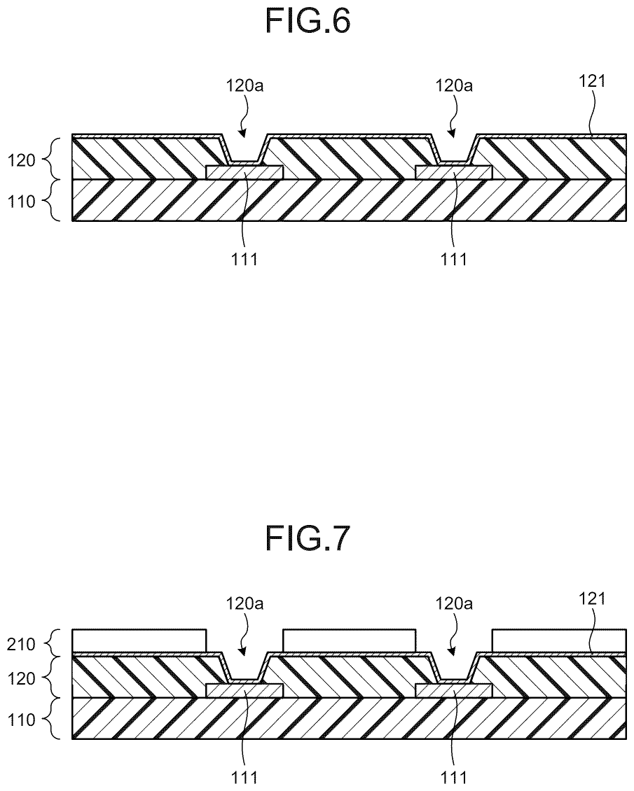

After formation of the via hole 120a, the seed layer 121 is formed on the top surface of the insulating layer 120 (step S103). Specifically, for example, as illustrated in FIG. 6, the seed layer 121 that continuously covers the top surface of the insulating layer 120, an inner surface of the via hole 120a, and the top surface of the insulating layer 110 exposed at the bottom portion of the via hole 120a is formed, for example, by sputtering or non-electrolytic plating. FIG. 6 is a diagram illustrating a specific example of a seed-layer formation process. As a material of the seed layer 121, for example, copper (Cu) is used.

After formation of the seed layer 121, a resist layer to form the pad main body 161 is formed on the top surface of the seed layer 121 (step S104). Specifically, for example, as illustrated in FIG. 7, on the seed layer 121, a resist layer 210 is formed in which an opening is arranged at a portion at which the pad main body 161 is formed, by patterning using exposure and development. FIG. 7 is a diagram illustrating a specific example of a resist-layer formation process. Because the pad main body 161 is formed at a position corresponding to the via hole 120a, the opening of the insulating layer 120 is formed at the position of the via hole 120a.

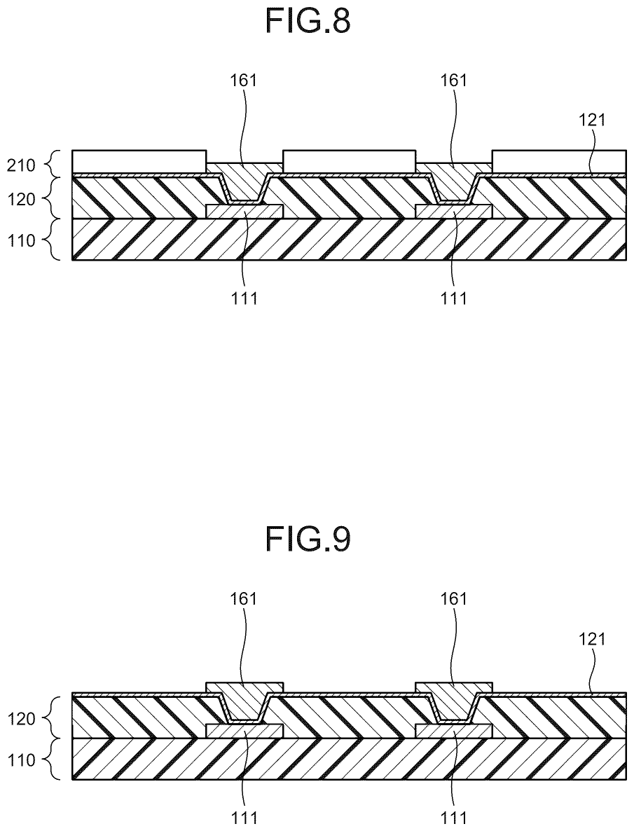

After the resist layer 210 is formed, the pad main body 161 is formed at the opening of the resist layer 210 by an electrolytic plating method using the seed layer 121 as a power supply layer (step S105). Specifically, for example, as illustrated in FIG. 8, inside the via hole 120a and inside the opening of the resist layer 210, for example, copper (Cu) is deposited, to form the pad main body 161. FIG. 8 is a diagram illustrating a specific example of an electrolytic plating process.

After the pad main body 161 is formed, the resist layer 210 is removed by, for example, an alkaline stripping solution (step S106). Thus, for example, as illustrated in FIG. 9, a structure in which the pad main body 161 protrudes upward from the seed layer 121 is obtained on the top surface of the insulating layer 120. FIG. 9 is a diagram illustrating a specific example of a resist-layer removal process.

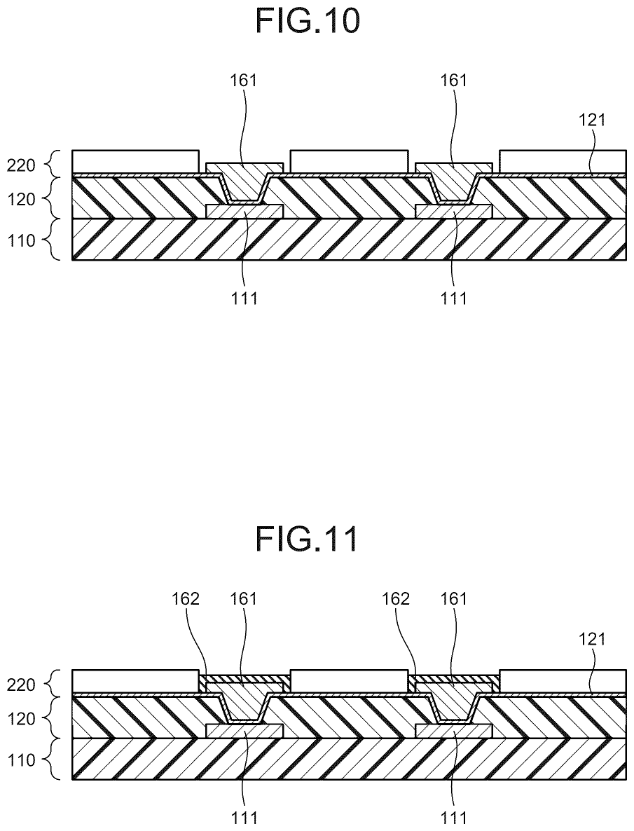

After removal of the resist layer 210, a resist layer to form the surface treatment layer 162 is formed on the top surface of the seed layer (step S107). Specifically, for example, as illustrated in FIG. 10, on the seed layer 121, a resist layer 220 is formed in which an opening is arranged at a portion at which the surface treatment layer 162 is formed, by patterning using exposure and development. FIG. 10 is a diagram illustrating a specific example of a resist-layer formation process.

After the resist layer 220 is formed, the surface treatment layer 162 is formed in the opening of the resist layer 220 by an electrolytic plating method using the seed layer 121 as a power supply layer (step S108). Specifically, for example, as illustrated in FIG. 11, the surface treatment layer 162 that covers the top surface and the side surface of the pad main body 161, and that reaches to the surface of the seed layer 121 is formed. FIG. 11 is a diagram illustrating a specific example of a surface-treatment-layer formation process. As the surface treatment layer 162, a gold (Au) layer is laminated on the top surface and the side surface of the pad main body 161. As the surface treatment layer 162, instead of the gold (Au) layer, a multilayer film constituted of a nickel (Ni) layer, a palladium (Pd) layer, and a gold (Au) layer, or a multilayer film constituted of a palladium (Pd) layer and a gold (Au) layer may be used. When a multilayer film is formed, the outermost layer of the surface treatment layer 162 is to be the gold (Au) layer.

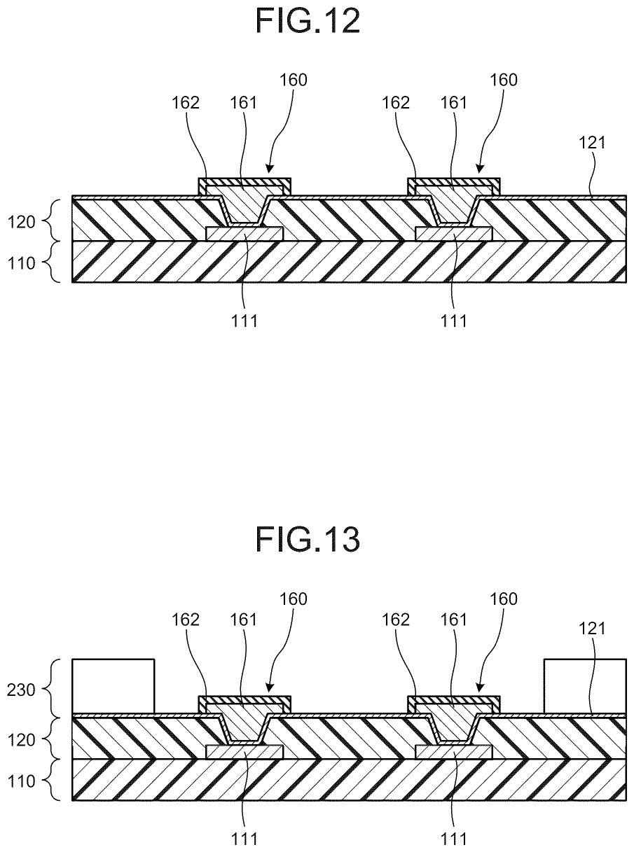

After the surface treatment layer 162 is formed, the resist layer 220 is removed by, for example, an alkaline stripping solution (step S109). Thus, for example, as illustrated in FIG. 12, the pad 160 including the pad main body 161 and the surface treatment layer 162 is formed on the top surface of the seed layer 121. At this stage, the seed layer 121 still remains on the entire surface, and the pad 160 is short-circuited with other pads. FIG. 12 is a diagram illustrating a specific example of a resist-layer removal process.

After removal of the resist layer 220, on the top surface of the seed layer 121, a resist layer to form a protective film to protect the pad 160 and the seed layer 121 around the pad 160 is formed (step S110). Specifically, for example, as illustrated in FIG. 13, a resist layer 230 is formed in which an opening is arranged at a portion at which a protective film is formed, by patterning using exposure and development, on the seed layer 121. FIG. 13 is a diagram illustrating a specific example of a resist-layer formation process.

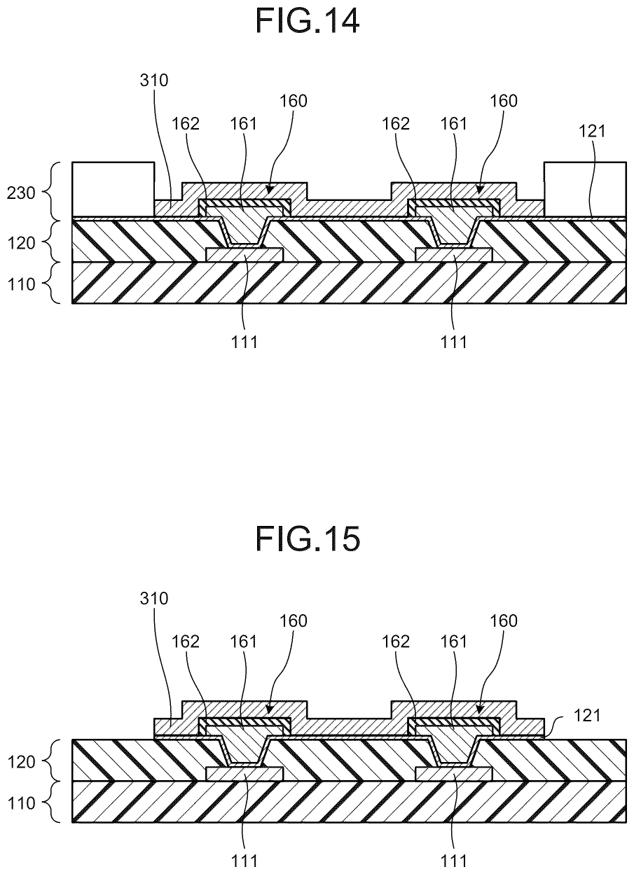

After the resist layer 230 is formed, the protective film is formed at the opening of the resist layer 230 by an electrolytic plating method using the seed layer 121 as a power supply layer (step S111). Specifically, for example, as illustrated in FIG. 14, a protective film 310 that covers a surface of the pad 160 and the top surface of the seed layer 121 around the pad 160 is formed. FIG. 14 is a diagram illustrating a specific example of a protective-film formation process. The thickness of the protective film 310 may be, for example, approximately 8 μm. As a material of the protective film 310, for example, a metal different from the surface treatment layer 162, that is, a gold (Au) layer, is used. In this example, as a material of the protective film 310, copper (Cu) is used similarly to the seed layer 121 and the pad main body 161, and the single layer protective film 310 made of copper (Cu) is to be formed. Formation of the protective film 310 is achieved by copper plating, for example, using a copper plating solution containing brightener (accelerator).

After the protective film 310 is formed, the resist layer 230 is removed by, for example, an alkaline stripping solution (step S112). Moreover, a portion of the seed layer 121 in contact with the resist layer 230 is removed by flash etching and, for example, as illustrated in FIG. 15, the insulating layer 120 is exposed in an area other than the portion in contact with the protective film 310. FIG. 15 is a diagram illustrating a specific example of a resist-layer removal process.

After removal of the resist layer 230, for example, as illustrated in FIG. 16, the insulating layer 130 that covers the surface of the protective film 310 is formed on the top surface of the insulating layer 120 (step S113). FIG. 16 is a diagram illustrating a specific example of an insulating-layer formation process. Although illustration is omitted in FIG. 16, after formation of the insulating layer 130, another wiring layer is formed on the top surface of the insulating layer 130, and this wiring layer is connected to the other wiring layer on the top surface of the insulating layer 120 by a via penetrating through the insulating layer 130. At this time, in a region in which the electronic component 170 is to be housed in the insulating layer 130, the other wiring layer and the via are not arranged. In the example in FIG. 16, because the electronic component 170 is to be housed in a region above the protective film 310 in the insulating layer 130, the other wiring layer and the via are not arranged in this region.

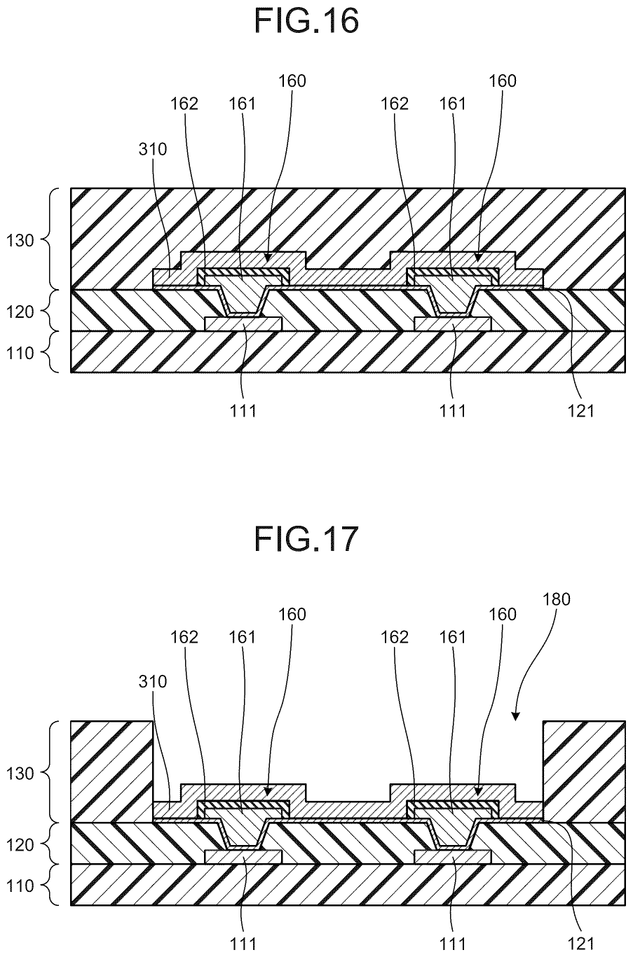

In the region in which the electronic component 170 is to be housed in the insulating layer 130, a cavity is formed (step S114). Specifically, for example, as illustrated in FIG. 17, the insulating layer 130 is cut off in a direction toward the protective film 310, to form a cavity 180. FIG. 17 is a diagram illustrating a specific example of a cavity formation process. The cavity formation process can be achieved by performing laser processing using, for example, a CO₂ laser. As the insulating layer 130 is cut off to the surface of the protective film 310, the surface of the protective film 310 is exposed at a bottom surface of the cavity 180.

In the cavity formation process, laser processing using a CO₂ laser is performed in a state in which the surface of the pad 160 and the top surface of the seed layer 121 around the pad 160 are covered with the protective film 310. Therefore, the CO₂ laser is not directly irradiated to the pad 160 and the seed layer 121 around the pad 160. In other words, the protective film 310 can shield the heat received by the pad 160 and the seed layer 121 around the pad 160 due to irradiation of the CO₂ laser. As a result, deterioration of the pad 160 and the seed layer 121 around the pad 160 caused by laser processing can be suppressed.

When the surface of the protective film 310 is exposed at the bottom surface of the cavity 180, the exposed protective film 310 is removed (step S115). That is, the protective film 310 is exposed at the bottom surface of the cavity 180 is removed by wet etching using a copper (Cu) etching solution. In this case, as the pad 160 and the seed layer 121 around the pad 160 are exposed, the copper (Cu) etching solution contacts and dissolves a portion of the seed layer 121 that does not overlap with the pad 160.

That is, as illustrated in FIG. 18, the protective film 310 is removed at the bottom surface of the cavity 180, and the portion of the seed layer 121 that does not overlap with the pad 160 is removed. Thus, the short circuit of the pad 160 with the other pad is resolved, and the pad 160 having the pad main body 161 and the surface treatment layer 162 is completed. FIG. 18 is a diagram illustrating a specific example of a protective-film removal process.

In the protective-film removal process, the portion of the seed layer 121 that does not overlap with the pad 160 is removed together with the protective film 310 and, therefore, compared to a case in which a process of removing an unnecessary portion of the seed layer 121 is separately performed, it is possible to improve manufacturing efficiency of the wiring substrate 100.

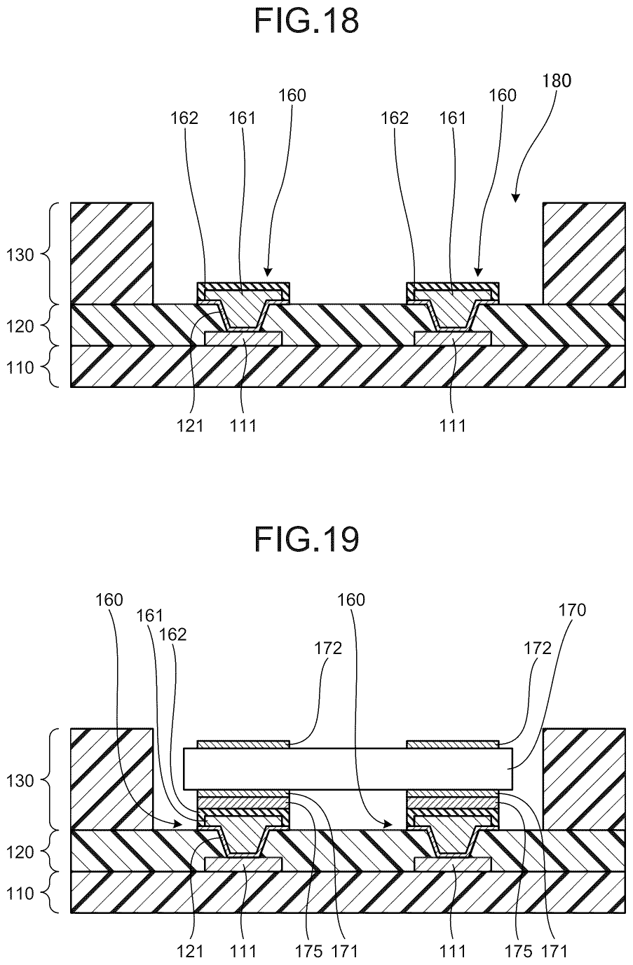

After the protective film 310 is removed, the electronic component 170 is mounted on the pad 160 inside the cavity 180 (step S116). Specifically, for example, as illustrated in FIG. 19, the electronic component 170 is housed in the cavity 180, and the lower electrode pad 171 of the electronic component 170 and the pad 160 are joined by the solder 175. FIG. 19 is a diagram illustrating a specific example of an electronic-component mounting process.

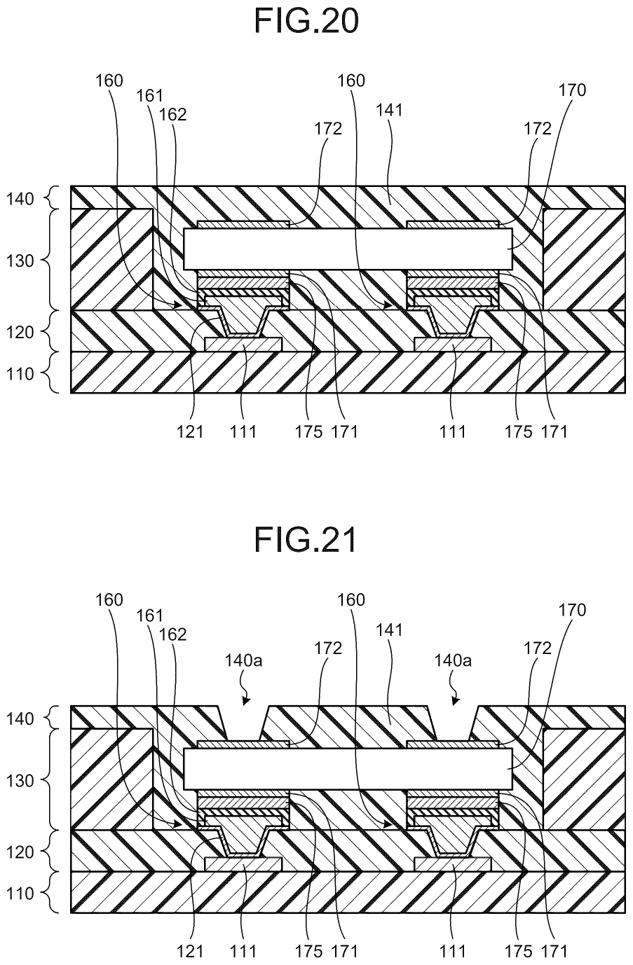

When the electronic component 170 is mounted on the pad 160, the filling resin 141 is filled in the cavity 180, and the electronic component 170 is embedded together with the pad 160 (step S117). That is, for example, as illustrated in FIG. 20, while the filling resin 141 is filled in the cavity 180, the filling resin layer 140 that extends above the electronic component 170 is formed. Thus, both the electronic component 170 and the pad 160 are embedded in the insulating layer 130, and the electronic component 170 is integrated in the wiring substrate 100. FIG. 20 is a diagram illustrating a specific example of an electronic-component embedding process. When the filling resin 141 is filled in the cavity 180 and the filling resin layer 140 is formed, the filling resin 141 is thermally cured.

Subsequently, a via hole is formed in the filling resin layer 140 (step S118). Specifically, for example, as illustrated in FIG. 21, a via hole 140a that penetrates through the filling resin layer 140, to expose the upper electrode pad 172 of the electronic component 170 is formed. FIG. 21 is a diagram illustrating a specific example of a via-hole formation process. The via hole 140a can be formed, for example, by laser processing. Although illustration is omitted in FIG. 21, another via hole that penetrates through the filling resin layer 140 and that exposes the other wiring on the top surface of the insulating layer 130 may be formed together with the via hole 140a by laser processing.

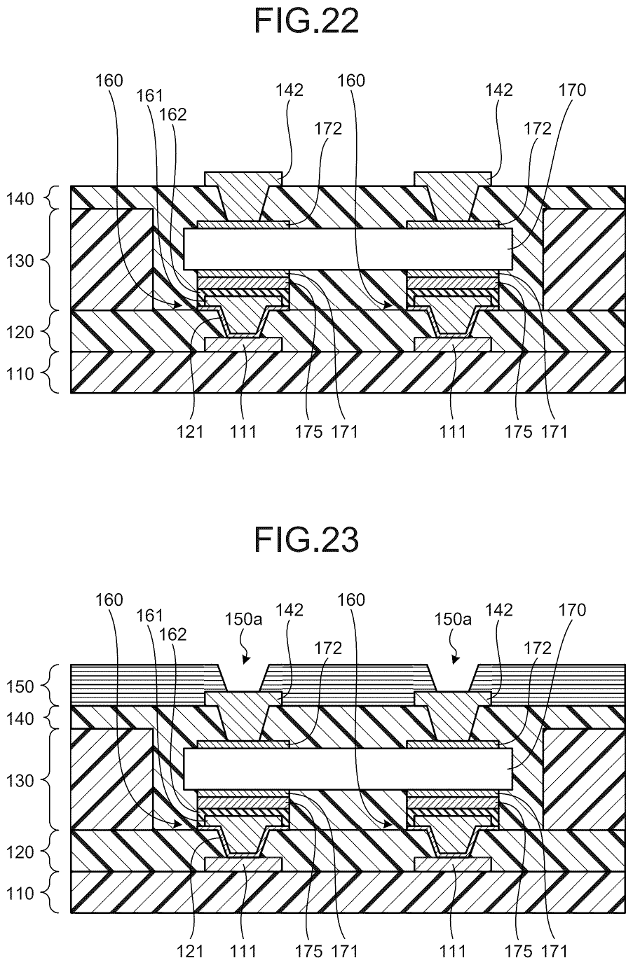

At a position at which the via hole 140a and the other via hole are formed, the wirings 142 on the top surface of the filling resin layer 140 are formed (step S119). That is, for example, as illustrated in FIG. 22, the wirings 142 are formed at the positions corresponding to the via hole 140a and the other via hole. FIG. 22 is a diagram illustrating a specific example of a wiring formation process. Formation of the wirings 142 is performed, for example, by semi-additive process (SAP). In SAP, a via that penetrates through the filling resin layer 140 is formed together with the wirings 142, and the wirings 142 on the top surface of the filling resin layer 140 and the upper electrode pad 172 of the electronic component 170 or the other wirings on the top surface of an insulating layer 130a are connected.

The wirings 142 on the top surface of the filling resin layer 140 are covered as the solder resist layer 150 is formed (step S120). The solder resist layer 150 is film-formed by, for example, pattern printing of insulating resin or the like. At the position corresponding to the wirings 142 on the top surface of the filling resin layer 140, for example, as illustrated in FIG. 23, the opening 150a is arranged in the solder resist layer 150. FIG. 23 is a diagram illustrating a specific example of a solder-resist-layer formation process. The opening 150a is formed by using, for example, photolithography, a laser, or the like. At the positions of these openings 150a, for example, an external component, such as a semiconductor chip, is arranged.

Accordingly, in the opening 150a, the bump 151 is formed by plating, a solder ball, or the like (step S121). The bump 151 serves as a contact point between the wirings 142 on the top surface of the filling resin layer 140 and an external component.

As described, in the manufacturing method of the wiring substrate 100 according to the first embodiment, the protective film 310 that covers the surface of the pad 160 formed on the top surface of the seed layer 121 and the seed layer 121 around the pad 160 is formed. In a state in which the surface of the pad 160 and the top surface of the seed layer 121 around the pad 160 are covered with the protective film 310, the cavity 180 to expose the protective film 310 is formed by laser processing using a CO₂ laser. Thus, the heat received by the pad 160 and the seed layer 121 around the pad 160 due to irradiation of the CO₂ laser can be shielded by the protective film 310. As a result, deterioration of the pad 160 and the seed layer 121 around the pad 160 caused by laser processing can be suppressed.

### Second Embodiment

In the first embodiment, a case in which the single layer protective film 310 made of cupper (Cu) by copper plating is formed on the surface of the pad 160 and the top surface of the seed layer 121 around the pad 160 has been explained. When the single layer protective film 310 is formed by cupper plating, variations in thickness of the protective film 310 may occur depending on electrolytic copper plating conditions applied to the copper plating.

Referring to FIG. 24, the mechanism by which variations in thickness of the protective film 310 occur will be explained. FIG. 24 is a diagram explaining variations in thickness of the protective film 310. The single layer protective film 310 made of copper (Cu) is formed by copper plating, for example, using a copper plating solution containing brightener (accelerator). That is, by applying copper plating for a predetermined time at a predetermined current density using the copper plating solution containing brightener, copper is deposited in the opening of the resist layer 230, and the protective film 310 is formed on the surface of the pad 160 and the top surface of the seed layer 121 around the pad 160. The thickness of the protective film 310 becomes relatively thin on the top surface of the pad 160 and relatively thick on the top surface of the seed layer 121 around the pad 160 as illustrated in FIG. 24. The reasons for occurrence of variations in thickness depending on a position as described are as follows.

That is, a flow of the copper plating solution containing brightener tends to stagnate on the side surface of the pad 160 or on the top surface of the seed layer 121 around the pad 160, compared to on the top surface of the pad 160. Therefore, the brightener that promotes a plating deposition process is less prone to adhere to the side surface of the pad 160 or the top surface of the seed layer 121 around the pad 160, compared to the top surface of the pad 160. As a result, compared to the top surface of the pad 160, the plating deposition amount on the side surface of the pad 160 and on the top surface of the seed layer 121 around the pad 160 increases, compared to on the top surface of the pad 160, and the thicker protective film 310 is formed on the side surface of the pad 160 or on the top surface of the seed layer 121 around the pad 160 than the top surface of the pad 160.

If the protective film 310 having variations in thickness depending on a position is formed as described, there is a possibility that the galvanic corrosion occurs on the surface treatment layer 162 of the pad 160 when the protective film 310 is removed.

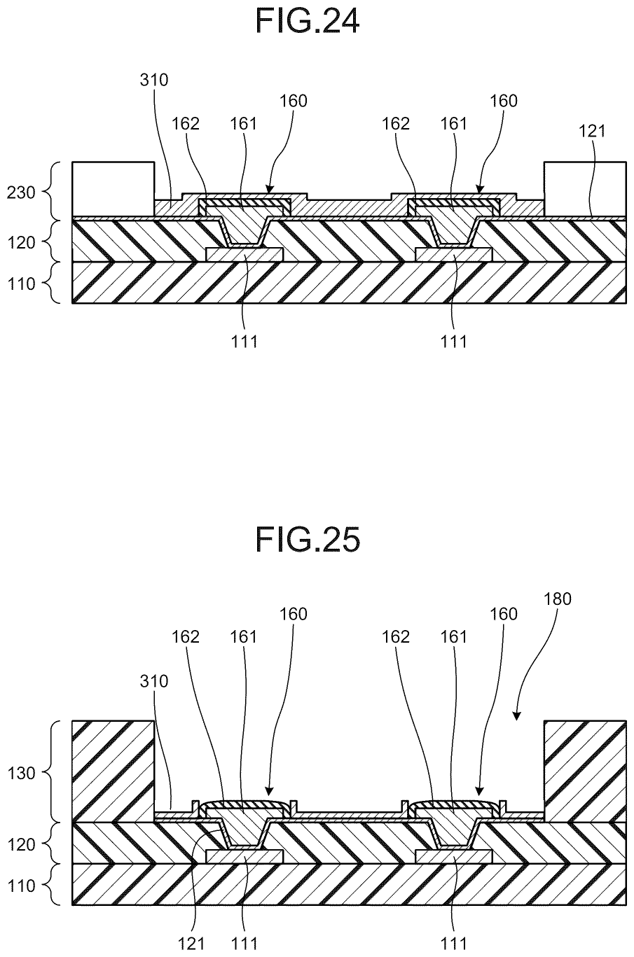

Referring to FIG. 25, the mechanism by which galvanic corrosion occurs on the surface treatment layer 162 will be explained. FIG. 25 is a diagram explaining how galvanic corrosion occurs on the surface treatment layer 162. The protective film 310 is removed by wet etching using a copper (Cu) etching solution. The thickness of the protective film 310 is thin on the top surface of the pad 160 compared to the side surface of the pad 160 and the top surface of the seed layer 121 around the pad 160. Therefore, the protective film 310 is removed earlier on the top surface of the pad 160 than the side surface of the pad 160 and the top surface of the seed layer around the pad 160 by wet etching, and the top surface of the pad 160 (the surface treatment layer 162) is to be exposed. On the other hand, the protective film 310 remains on the side surface of the pad 160 and the top surface of the seed layer 121 around the pad 160. The remaining protective film 310 and the surface treatment layer 162 of the pad 160 then come into contact under the etching solution. While a metal forming the protective film 310 is copper (Cu), a metal forming the surface treatment layer 162 is gold (Au). Thus, a cell is formed with the surface treatment layer 162, the remaining protective film 310, and the etching solution. As a result, dissimilar metal corrosion, namely galvanic corrosion, occurs on the surface treatment layer 162. The example in FIG. 25 illustrates how the galvanic corrosion occurs near a contact portion between the surface treatment layer 162 and the remaining protective film 310.

As explained so far, when the single layer protective film 310 is formed, variations in thickness of the protective film 310 occur and, therefore, there is a possibility that galvanic corrosion occurs on the surface treatment layer 162 when removal of the protective film 310 is performed by wet etching.

Therefore, in the second embodiment, the thickness of a protective film is uniformized by forming a multilayer protective film by laminating multiple metal films, and occurrence of galvanic corrosion on the surface treatment layer 162 when the protective film is removed by wet etching is suppressed.

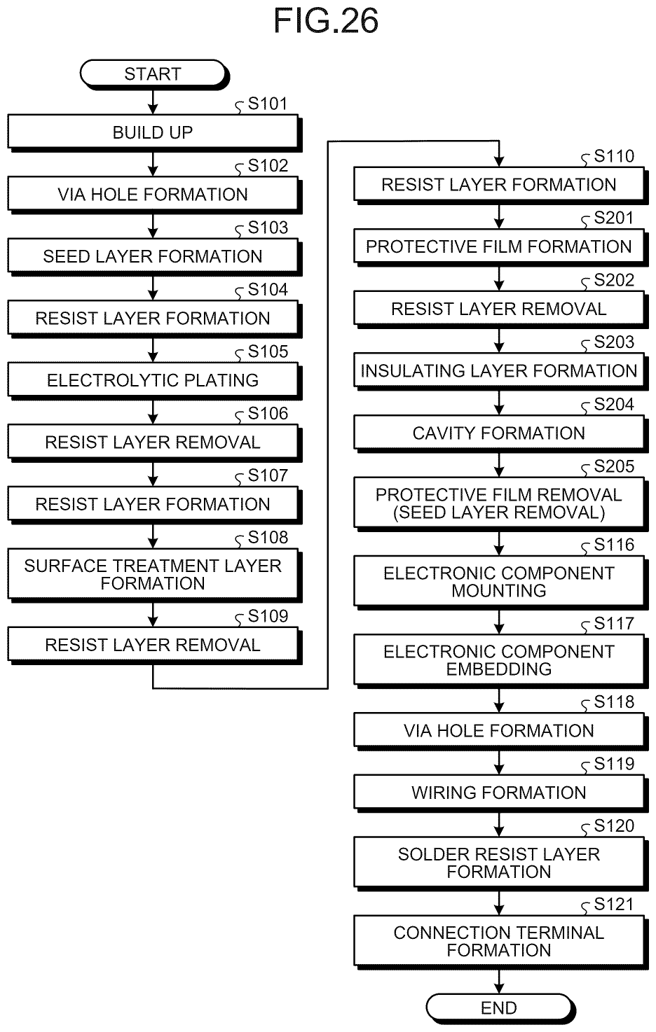

FIG. 26 is a flowchart illustrating a manufacturing method of the wiring substrate 100 according to the second embodiment. In FIG. 26, identical reference symbols are assigned to components identical to those in FIG. 3. In the manufacturing method of the wiring substrate 100 illustrated in FIG. 26, after the resist layer 230 is formed at step S110, a multilayer protective film is formed by laminating multiple metal films.

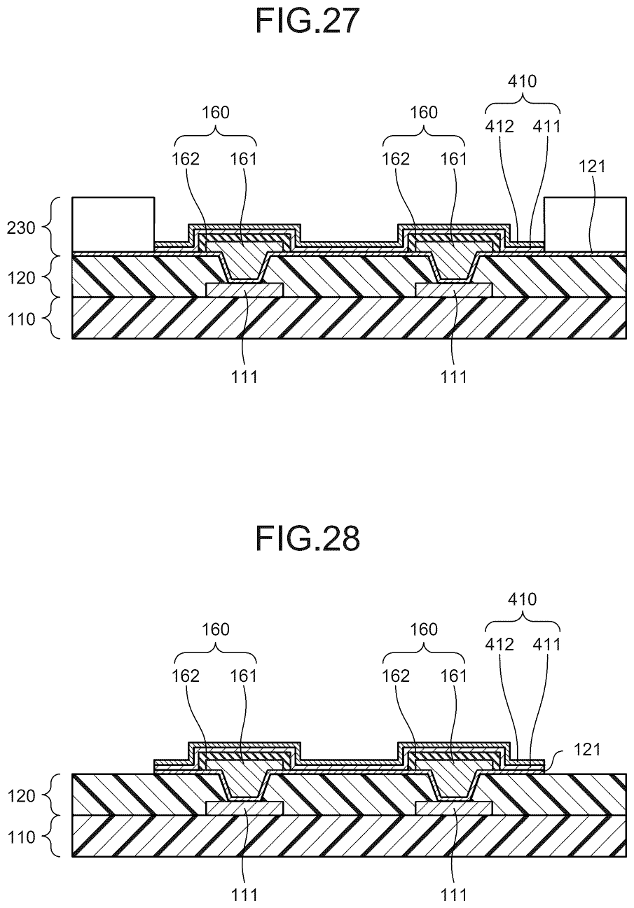

When the resist layer 230 is formed, a multilayer protective film is formed by laminating multiple metal films at an opening of the resist layer 230 by electrolytic plating using the seed layer 121 as a power supply layer (step S201). Specifically, for example, as illustrated in FIG. 27, a first metal film 411 and a second metal film 412 are laminated to form a protective film 410 that covers the surface of the pad 160 and the top surface of the seed layer 121 around the pad 160. FIG. 27 is a diagram illustrating a specific example of a protective-film formation process. The thickness of the protective film 410 can be set to, for example, approximately 8 μm. The thicknesses of the first metal film 411 and the second metal film 412 are preferable to be equal to or smaller than the thickness of the surface treatment layer 162, and may be set to, for example, approximately 4 μm.

As a material of the first metal film 411, a metal different from that of the surface treatment layer 162, that is, the gold (Au) layer, is used. In this example, as a material of the first metal film 411, copper (Cu) is used similarly to the seed layer 121 and the pad main body 161. Formation of the first metal film 411 is achieved by copper plating using a copper plating solution containing, for example, brightener (accelerator). The first metal film 411 is arranged in contact with the seed layer 121 at a lower most layer of the protective film 410.

Moreover, as a material of the second metal film 412, a metal that is different from the surface treatment layer 162, that is, the gold (Au) layer, is used. In this example, as a material of the second metal film 412, nickel (Ni) having a thermal conductivity lower than copper (Cu), which is the material of the first metal film 411, is used. Formation of the second metal film 412 is achieved by nickel plating using a nickel plating solution containing, for example, brightener (accelerator). The second metal film 412 is arranged on the uppermost layer of the protective film 410.

By forming the multilayer protective film 410 by laminating the first metal film 411 and the second metal film 412, the thicknesses of the first metal film 411 and the second metal film 412 can be reduced. In other words, when the first metal film 411 and the second metal film 412 are formed, a current density in copper plating or nickel plating can be reduced, and acceleration of plating deposition caused by the brightener in the plating solution can be suppressed. Thus, it is possible to suppress occurrence of variations in thicknesses of the first metal film 411 and the second metal film 412 depending on a position and, therefore, the protective film 410 can be formed with uniform thickness along the surface of the pad 160 and the top surface of the seed layer 121 around the pad 160.

Moreover, by making each of the thicknesses of the first metal film 411 and the second metal film 412 equal to or smaller than the thickness of the surface treatment layer 162, the thickness of the protective film 410 can be further uniformized.

When the protective film 410 is formed, the resist layer 230 is removed by, for example, an alkaline stripping solution (step S202). Moreover, a portion of the seed layer 121 in contact with the resist layer 230 is removed by flash etching and, for example, as illustrated in FIG. 28, the insulating layer 120 is exposed in a region other than the portion in contact with the protective film 310. FIG. 28 is a diagram illustrating a specific example of a resist-layer removal process.

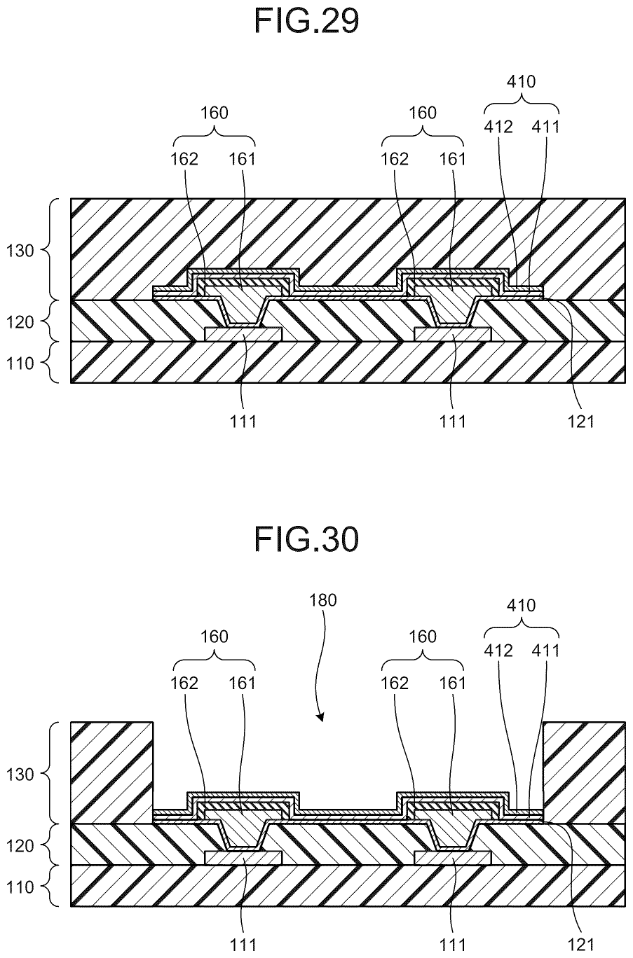

After the resist layer 230 is removed, for example, as illustrated in FIG. 29, the insulating layer 130 that covers the surface of the protective film 410 is formed on the top surface of the insulating layer 120 (step S203). FIG. 29 is a diagram illustrating a specific example of an insulating-layer formation process. Although illustration is omitted in FIG. 29, after formation of the insulating layer 130, another wiring layer is formed on the top surface of the insulating layer 130, and this wiring layer is connected to another wiring layer on the top surface of the insulating layer 120 by a via that penetrates through the insulating layer 130. In this case, in a region in which the electronic component 170 is to be housed in the insulating layer 130, the other wiring layer and the via are not arranged. In the example in FIG. 29, because the electronic component 170 is to be housed in a region above the protective film 410 in the insulating layer 130, the other wiring layer and the via are not arranged in this region.

Subsequently, in the region in which the electronic component 170 is to be house in the insulating layer 130, a cavity is formed (step S204). Specifically, for example, as illustrated in FIG. 30, the insulating layer 130 is cut off in a direction toward the protective film 410, to form the cavity 180. FIG. 30 is a diagram illustrating a specific example of a cavity formation process. The cavity formation process can be achieved by using laser processing using, for example, a CO₂ laser. As the insulating layer 130 is cut off to the surface of the protective film 410, the surface of the protective film 410 is exposed at a bottom surface of the cavity 180.

In the cavity formation process, laser processing using a CO₂ laser is performed in a state in which the surface of the pad 160 and the top surface of the seed layer 121 around the pad 160 are covered with the protective film 410. Therefore, the CO₂ laser is not directly irradiated to the pad 160 and the seed layer 121 around the pad 160. In other words, the protective film 410 can shield the heat received by the pad 160 and the seed layer 121 around the pad 160 due to irradiation of the CO₂ laser. As a result, deterioration of the pad 160 and the seed layer 121 around the pad 160 caused by laser processing can be suppressed.

In the cavity formation process, the cavity 180 that exposes a surface of the second metal film 412 arranged at the uppermost layer of the protective film 410 is formed in the insulating layer 130 by laser processing. Nickel (Ni) forming the second metal film 412 has lower thermal conductivity than copper (Cu) forming the first metal film 411. Therefore, the second metal film 412 is less prone to transfer heat received by irradiation of a CO₂ laser to the pad 160 and the seed layer 121 around the pad 160. As a result, deterioration of the pad 160 and the seed layer 121 around the pad 160 caused by laser processing can be suppressed.

When the surface of the protective film 410 (the second metal film 412) is exposed to the bottom surface of the cavity 180, the exposed protective film 410 is removed (step S205). That is, the second metal film 412 and the first metal film 411 constituting the protective film 410 are removed in this order. First, by wet etching using an etching solution for nickel (Ni), the second metal film 412 exposed at the bottom surface of the cavity 180 is removed. Subsequently, by wet etching using an etching solution for copper (Cu), the first metal film 411 is removed. At this time, as the pad 160 and the seed layer 121 around the pad 160 are exposed, the etching solution for copper (Cu) comes in contact with and dissolves the seed layer 121 in a portion that does not overlap with the pad 160. That is, the first metal film 411 is removed and the portion of the seed layer 121 that does not overlap with the pad 160 are removed. Thus, the short circuit between the pad 160 and the other pad is resolved, and the pad 160 having the pad main body 161 and the surface treatment layer 162 is completed.

Because the protective film 410 has a uniform thickness, in the protective-film removal process, just etching that removes the entire protective film 410 is substantially simultaneously removed by wet etching can be achieved. Thus, the possibility of formation of a cell with the surface treatment layer 162, the protective film 410, and the etching solution can be reduced, and occurrence of dissimilar metal corrosion, namely galvanic corrosion, on the surface treatment layer 162 is suppressed.

Moreover, in the protective-film removal process, because the portion of the seed layer 121 that does not overlap with the pad 160 is removed together with the first metal film 411, compared to a case in which a process of removing an unnecessary portion of the seed layer 121 is separately performed, it is possible to improve manufacturing efficiency of the wiring substrate 100.

As described, in the manufacturing method of the wiring substrate 100 according to the second embodiment, the multilayer protective film 410 is formed by laminating the first metal film 411 and the second metal film 412, to uniformize the thickness of the protective film 410. Thus, the entire protective film 410 can be removed substantially simultaneously when the protective film 410 is removed by wet etching and, therefore, the possibility of formation of a cell with the surface treatment layer 162, the protective film 410, and the etching solution can be reduced. As a result, occurrence of galvanic corrosion on the surface treatment layer 162 can be suppressed.

### Modification of Second Embodiment

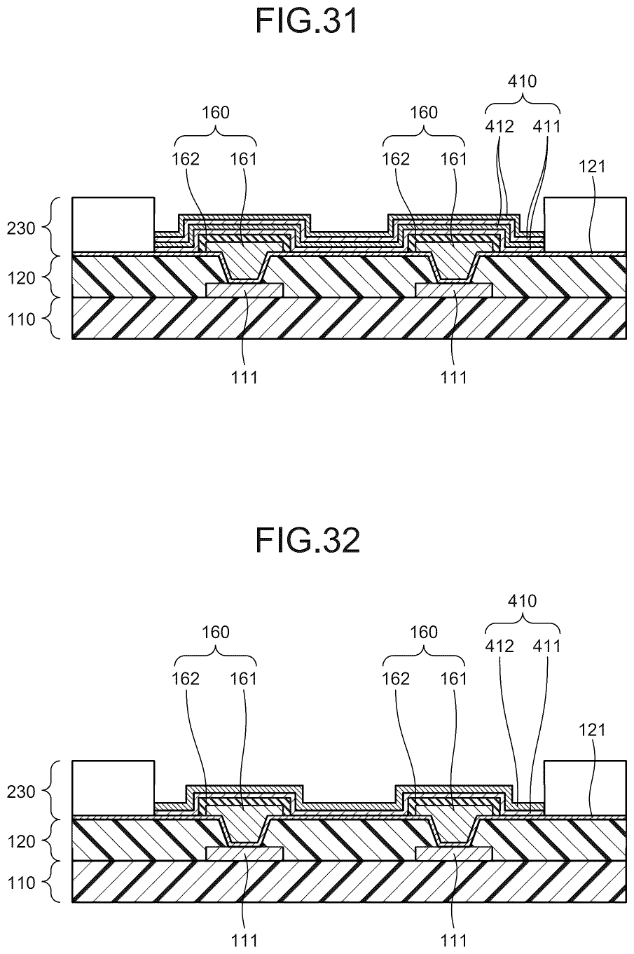

Next various modifications of the second embodiment will be explained referring to FIG. 31 and FIG. 32. In the respective modifications described below, duplicated explanation may be omitted by assigning identical reference symbols to components identical to those in the embodiments.

In the second embodiment described above, the single first metal film 411 and the single second metal film 412 are laminated, to form the protective film 410, but the multilayer structure of the protective film 410 is not limited thereto. Specifically, for example, as illustrated in FIG. 31, the multiple (two in this example) first metal films 411 and the multiple (two in this example) second metal films 412 may be alternately laminated, to form the protective film 410. FIG. 31 is a diagram illustrating a first modification of a protective-film formation process. The thickness of the protective film 410 may be, for example, approximately 8 μm. Each of the thicknesses of the first metal film 411 and the second metal film 412 are preferable to be equal to or smaller than the thickness of the surface treatment layer 162, and may be, for example, approximately 2 μm.

By laminating the multiple first metal films 411 and the multiple second metal films 412 alternately, the thicknesses of the first metal film 411 and the second metal film 412 can each be reduced. This enables to further suppress occurrence of variations in thicknesses of the first metal film 411 and the second metal film 412 depending on a position and, therefore, the protective film 410 can be formed in a uniform thickness.

Moreover, in the second embodiment described above, a case in which the thicknesses of the first metal film 411 and the second metal film 412 in the protective film 410 are equal to each other has been explained, but the thicknesses of the first metal film 411 and the second metal film 412 may be different from each other. Specifically, for example, as illustrated in FIG. 32, the thickness of the second metal film 412 may be formed thicker than the thickness of the first metal film 411 when the protective film 410 is formed. FIG. 32 is a diagram illustrating a second modification of the protective-film formation process.

Nickel (Ni) forming the second metal film 412 has lower thermal conductivity than copper (Cu) forming the first metal film 411. Because the thickness of the second metal film 412 is thicker than the thickness of the first metal film 411, in the cavity formation process using laser processing, the second metal film 412 is less prone to transfer heat received by irradiation of a CO₂ laser to the pad 160 and the seed layer 121 around the pad 160. As a result, deterioration of the pad 160 and the seed layer 121 around the pad 160 caused by laser processing can be suppressed.

Furthermore, in the second embodiment described above, the first metal film 411 is arranged at the lowermost layer of the protective film 410, in contact with the seed layer 121, and the second metal film 412 is arranged at the uppermost layer of the protective film 410, but the arrangement positions of the first metal film 411 and the second metal film 412 may be reversed. That is, the second metal film 412 may be arranged at the lowermost layer of the protective film 410, in contact with the seed layer 121, and the first metal film 411 may be arranged at the uppermost layer of the protective film 410.

As described above, the manufacturing method of a wiring substrate (the wiring substrate 100 as an example) according to the embodiments includes a process (step S103 as an example) of laminating a seed layer (the seed layer 121 as an example) made of a metal on a top surface of a first insulating layer (the insulating layer 120 as an example), a process (steps S105, S108 as an example) of forming a pad (the pad 160 as an example) including a pad main body (the pad main body 161 as an example) made of a metal, and a surface treatment layer (the surface treatment layer 162 as an example) that covers a top surface and a side surface of the pad main body and that has a metal layer (the gold (Au) layer as an example) made of a metal different from that of the pad main body at least in part, a process (steps S111, S201) of forming a protective film (the protective films 310, 410 as an example) that covers a surface of the pad and a top surface of the seed layer around the pad, a process (steps S114, S204 as an example) of forming a cavity (the cavity 180 as an example) that exposes a surface of the protective film in a second insulating layer by laser processing, a process (steps S115, S205 as an example) of removing the protective film exposed in the cavity by etching, and a process (steps S115, S205 as an example) of removing a position of the seed layer that does not overlap with the pad. As a result, deterioration of the pad and the seed layer around the pad caused by laser processing can be suppressed.

According to one aspect of the manufacturing method of a wiring substrate disclosed in the present application, an effect of suppressing deterioration of a pad and a seed layer around the pad caused by laser processing is achieved.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A manufacturing method of a wiring substrate comprising:
laminating a seed layer that is made of a metal on a top surface of a first insulating layer;
forming, on a top surface of the seed layer, a pad that includes a pad main body made of a metal, and a surface treatment layer that covers a top surface and a side surface of the pad main body, and that has a metal layer made of a metal different from that of the pad main body at least in part;
forming a protective film that covers a surface of the pad and the top surface of the seed layer around the pad;
forming a second insulating layer that covers a surface of the protective film on the top surface of the first insulating layer;
forming a cavity that exposes the surface of the protective film in the second insulating layer by laser processing;
removing the protective film that is exposed in the cavity, by etching; and
removing a portion of the seed layer that does not overlap with the pad.

2. The manufacturing method of a wiring substrate according to claim 1, further comprising:
mounting an electronic component on the pad inside the cavity; and
forming a filling resin layer that covers the electronic component and the pad by filling the cavity.

3. The manufacturing method of a wiring substrate according to claim 1, wherein
the forming the protective film includes forming the protective film of a single layer made of a metal that is different from that of the metal layer of the surface treatment layer.

4. The manufacturing method of a wiring substrate according to claim 3, wherein
the metal forming the protective film is a metal same as the metal forming the seed layer, and
the removing the portion of the seed layer is performed in parallel with the removing the protective film.

5. The manufacturing method of a wiring substrate according to claim 1, wherein
the forming the protective film includes forming the protective film by laminating a first metal film made of a first metal that is different from that of the metal layer of the surface treatment layer and a second metal film made of a second metal that is different from that of the metal layer of the surface treatment layer and the first metal.

6. The manufacturing method of a wiring substrate according to claim 5, wherein
each of thicknesses of the first metal film and the second metal film is equal to or smaller than a thickness of the surface treatment layer.

7. The manufacturing method of a wiring substrate according to claim 5, wherein
the forming the protective film includes forming the protective film by alternately laminating a plurality of the first metal films and a plurality of the second metal films.

8. The manufacturing method of a wiring substrate according to claim 5, wherein
the first metal forming the first metal film is a metal identical to a metal forming the seed layer,
the forming the protective film includes forming the protective film by laminating the first metal film and the second metal film such that the first metal film is arranged at a lowermost layer of the protective film, in contact with the seed layer,
the removing the protective film includes removing the first metal film that is arranged at the lowermost layer of the protective film,
the removing the portion of the seed layer is performed in parallel with the removing the first metal film.

9. The manufacturing method of a wiring substrate according to claim 5, wherein
the second metal forming the second metal film is a metal having lower thermal conductivity than the first metal forming the first metal film,
the forming the protective film includes forming the protective film by laminating the first metal film and the second metal film such that the second metal film is arranged at an uppermost layer of the protective film,
the forming the cavity includes forming the cavity that exposes a surface of the second metal film in the second insulating layer by the laser processing.

10. The manufacturing method of a wiring substrate according to claim 5, wherein
the second metal forming the second metal film is a metal having lower thermal conductivity than the first metal forming the first metal film, and
the forming the protective film includes making a thickness of the second metal film thicker than a thickness of the first metal film in the protective film.
